(19) United States
(12) Patent Application Publication
(10) Pub. No.: US 2009/0242956 A1
(43) Pub. Date: Oct. 1, 2009

(54) TUNNEL DIELECTRICS FOR SEMICONDUCTOR DEVICES

(76) Inventors: Jiunn B. Heng, San Jose, CA (US); Sanjib Saha, Fremont, CA (US); Richard M. Fastow, Cupertino, CA (US)

Correspondence Address: COOL PATENT, P.C.;c/o CPA Global, P.O. BOX 52050, MINNEAPOLIS, MN, 55402, US

(21) Appl. No.: 12/057,375

(22) Filed: Mar. 28, 2008

(51) Int. Cl. H01L 29/788; H01L 21/336

(52) U.S. Cl. 257/316; 438/264; 257/E29.3; 257/E21.409

(57) ABSTRACT

Tunnel dielectrics for semiconductor devices are generally described. In one example, an apparatus includes a semiconductor substrate, a first tunnel dielectric having a first bandgap coupled to the semiconductor substrate, a second tunnel dielectric having a second bandgap coupled to the first tunnel dielectric, and a third tunnel dielectric having a third bandgap coupled to the second tunnel dielectric wherein the second bandgap is relatively smaller than the first bandgap and the third bandgap.

### BACKGROUND

Generally, the scaling of memory such as floating gate or trap-based flash memory may be limited by high electric fields applied to dielectrics surrounding a charge-trap element. Charge retention targets and program/erase cycling reliability targets may further restrict erase-voltage scaling of memory technology.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIG. 1 is an elevation cross-section schematic of an electronic device comprising a tunnel dielectric structure, according to but one embodiment;

FIG. 2 is a band diagram of an electronic device comprising a tunnel dielectric structure as described herein, according to but one embodiment;

FIG. 3 is a flow diagram of a method for fabricating an electronic device comprising a tunnel dielectric structure, according to but one embodiment; and

FIG. 4 is a diagram of an example system in which an electronic device comprising a tunnel dielectric structure as described herein may be used, according to but one embodiment.

For simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments of tunnel dielectrics for semiconductor devices such as memory devices are described herein. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout the specification to “one embodiment” or “an embodiment” means that a particular feature, structure or characteristic described in connection with the embodiment is included in at least one embodiment. Thus, appearances of the phrases “in one embodiment” or “in an embodiment” in various places throughout the specification are not necessarily referring to the same embodiment. Furthermore, the particular features, structures or characteristics may be combined in any suitable manner in one or more embodiments.

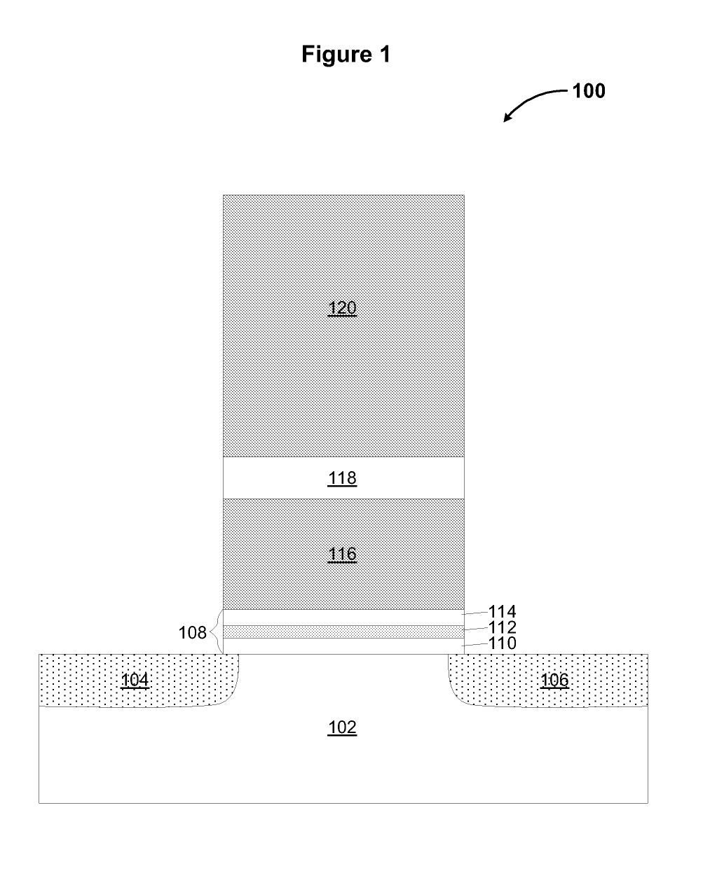

FIG. 1 is an elevation cross-section schematic of an electronic device comprising a tunnel dielectric structure, according to but one embodiment. In an embodiment, an electronic device 100 includes a semiconductor substrate 102 having source 104 and drain 106 regions, a tunnel dielectric structure 108 comprising a first tunnel dielectric 110, a second tunnel dielectric 112, and a third tunnel dielectric 114, coupled as shown. In another embodiment, electronic device 100 further includes a charge trap structure 116, an inter-gate dielectric structure 118, and a control gate structure 120, coupled as shown.

Bandgap characteristics of a tunnel dielectric structure 108 as disclosed herein may allow for increased electron tunneling compared with a tunneling dielectric structure 108 that comprises a single tunnel dielectric having a single bandgap such as, for example, a single layer of silicon oxide. An electronic device 100 as disclosed herein may be used in n-type or p-type planar or non-planar semiconductor devices including, for example, flash memory devices such as floating gate or trap-based flash memory. In other embodiments, an electron device 100 may be used in other semiconductor devices.

An electronic device 100 may include a semiconductor substrate 102, a first tunnel dielectric 110 having a first bandgap coupled to the semiconductor substrate 102, a second tunnel dielectric 112 having a second bandgap coupled to the first tunnel dielectric 110, and a third tunnel dielectric 114 having a third bandgap coupled to the second tunnel dielectric 112. In an embodiment, the second bandgap is relatively smaller than the first bandgap and relatively smaller than the third bandgap. In another embodiment, a first bandgap has a value of about 8.5 electron volts (eV) to about 9.5 eV, the second bandgap has a value of about 4.2 eV to about 5.2 eV, and the third bandgap has a value about 8.5 eV to about 9.5 eV.

An electron device 100 such as a floating gate transistor, for example, which incorporates a multi-layered tunnel dielectric structure 108 as described herein may experience increased electron tunneling during an erase condition. Increased electron tunneling may result from a Fowler-Nordheim mechanism that allows for a reduction of an erase voltage applied to the control gate 120. A tunnel dielectric structure 108 as disclosed herein may also allow a charge trap structure 116 such as a floating gate or other charge-trap element to retain a charge under a typical program condition. Charge retention and/or increased electron tunneling may increase program/erase cycling reliability of an electronic device 100 and, thus, allow for erase voltage scaling of the electronic device 100. A tunnel dielectric structure 108 may comprise silicon oxide, silicon nitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or combinations thereof.

In an embodiment, a first tunnel dielectric 110 comprises silicon oxide (SiO₂), a second tunnel dielectric 112 comprises silicon nitride (SiN) (Si₃N₄), tantalum pentoxide (Ta₂O₅), titanium dioxide (TiO₂), aluminum oxide (Al₂O₃), or combinations thereof, and a third tunnel dielectric 114 comprises silicon oxide (SiO₂). In other embodiments, other suitable dielectric materials may be used to form tunnel dielectric structure 108.

A first tunnel dielectric 110 may have a thickness that is relatively larger than a thickness of a third tunnel dielectric 114 to increase charge retention of electronic device 100. In an embodiment, the first tunnel dielectric 112 has a thickness of about 5 nanometers (nm) to about 7 nm. Other thicknesses may be used for a first tunnel dielectric 112 in other embodiments. In another embodiment, first tunnel dielectric 110 is deposited to a semiconductor substrate 102 by an oxidation method. For example, first tunnel dielectric 110 may be grown on semiconductor substrate 102 by a thermal process such as diffusion.

A second tunnel dielectric 112 may have a thickness that is thin enough to allow programming of an electronic device 100 and thick enough to allow or increase tunneling in electronic device 100. Reducing a thickness of a second tunnel dielectric 112 may reduce electron trapping, which may, in turn, improve or increase programmability of an electronic device 100. In an embodiment, second tunnel dielectric 112 comprises a thickness that is sufficiently thin to allow programming of an electronic device 100 that incorporates the second tunnel dielectric 112. In another embodiment, second tunnel dielectric 112 comprises a thickness that is sufficiently thick to allow or increase electron tunneling in electronic device 100. The second tunnel dielectric 112 may have a thickness of about 1 nm to about 2 nm. Other thicknesses may be used for a second tunnel dielectric 112 in other embodiments.

Second tunnel dielectric 112 may be deposited to a first tunnel dielectric 110 by a deposition method such as chemical vapor deposition (CVD), physical vapor deposition (PVD), atomic layer deposition (ALD), or combinations thereof. In another embodiment, second tunnel dielectric 112 is formed by a reduction technique such as plasma reduction, for example, that converts a first tunnel dielectric 110 into a second tunnel dielectric 112 wherein the second tunnel dielectric 112 has a lower bandgap than the first tunnel dielectric 110. For example, a reduction technique may convert a first tunnel dielectric 110 comprising silicon oxide (SiO₂) to a second tunnel dielectric 110 comprising silicon nitride (SiN) (Si₃N₄) according to one embodiment.

Trap defects may compromise the integration of a second tunnel dielectric 112 and a multi-layer tunnel dielectric structure 108. Trap defects may include electronic defects such as broken bonds or other electron traps in a tunnel dielectric structure 108 or at interfaces between a first tunnel dielectric 110, a second tunnel dielectric 112, and a third tunnel dielectric 114. Trap defects may be reduced in a tunnel dielectric structure 108 by using material replacement or material conversion techniques such as oxidation and/or reduction to form the first tunnel dielectric 110, second tunnel dielectric 112, and/or third tunnel dielectric 114. In an embodiment, a second tunnel dielectric 112 comprises few or substantially no trap defects in the second tunnel dielectric 112 material. In another embodiment, a second tunnel dielectric 112 comprises few or substantially no trap defects at the interfaces between the second tunnel dielectric 112 and the first 110 and third 114 tunnel dielectrics.

A third tunnel dielectric 114 may have a thickness that is relatively smaller than a thickness of a first tunnel dielectric 110 to allow electron tunneling from a charge trap structure 116 such as a floating gate to a semiconductor substrate 102 wherein the semiconductor substrate 102 comprises a transistor channel. The third tunnel dielectric 114 may have a thickness of about 1.5 nm to about 2.5 nm. Other thicknesses may be used for a third tunnel dielectric 114 in other embodiments.

A third tunnel dielectric 114 may be formed on second tunnel dielectric 112 by an oxidation process such as plasma oxidation. For example, an oxidation process may convert a second tunnel dielectric 112 comprising silicon nitride (SiN) (Si₃N₄) to a third tunnel dielectric 114 comprising silicon oxide (SiO₂) according to one embodiment. Oxidation may reduce trap defects compared with other deposition techniques such as CVD. Other deposition methods that provide few or substantially no trap defects at an interface between a third tunnel dielectric 114 and second tunnel dielectric 112 may be used in other embodiments.

An electronic device 100 may comprise a transistor wherein the first tunnel dielectric 110, the second tunnel dielectric 112, and the third tunnel dielectric 114 form a tunnel dielectric structure 108 of the transistor that increases electron tunneling in the transistor. A tunnel dielectric structure 108 as described herein may reduce a voltage for a typical erase condition without compromising charge retention in an electronic device 100. Tunnel dielectric structure 108 may also increase reliability of program/erase cycling of an electronic device 100 allowing potential scaling of the electronic device 100.

Electronic device 100 may further comprise a charge trap structure 116 coupled to the third tunnel dielectric 114. In an embodiment, charge trap structure 116 comprises a floating gate structure. In another embodiment, charge trap structure 116 comprises a trap-based structure or other charge-trap element. Charge trap structure 116 may comprise polysilicon, silicon nitride (SiN), or combinations thereof. Materials for a charge trap structure 116 may be doped to favor electrical conductivity. Charge trap structure 116 may include any other suitable gate electrode material in other embodiments.

An inter-gate dielectric structure 118 may be coupled to the charge trap structure 116. In an embodiment, inter-gate dielectric structure 118 comprises silicon oxide, silicon nitride, aluminum oxide, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, lead scandium tantalum oxide, lead zinc niobate, or combinations thereof. Other suitable materials may be used to form an inter-gate dielectric structure 118 in other embodiments. In an embodiment, inter-gate dielectric structure 118 comprises a multi-material silicon oxide/silicon nitride/silicon oxide arrangement.

A control gate structure 120 may be coupled to the inter-gate dielectric structure 118. In an embodiment, control gate structure 120 comprises polysilicon, metal silicide, metal, or combinations thereof In other embodiments, other suitable electrode materials are used in a control gate structure 120. Control gate structure 102 may be electrically coupled with other structures (not shown) that supply voltages to electronic device 100.

A source region 104 and drain region 106 may be formed in a semiconductor substrate 102 of electronic device 100. In an embodiment, semiconductor substrate 102 comprises silicon. Source region 104 and drain region 106 may be doped with impurities by an implant process to change the electrical properties of the semiconductor substrate 102 material in said regions 104, 106. For an n-type electronic device 100, a source region 104 and drain region 106 may be doped with arsenic (As), phosphorous (P), or combinations thereof. Other n-type dopants may be used in other embodiments. For a p-type electronic device 100, a source region 104 and drain region 106 may be doped with boron (B), aluminum (Al), or combinations thereof. Other p-type dopants may be used in other embodiments. Other semiconductor fabrication processes such as lithography, etch, thin films deposition, implant, planarization, diffusion, metrology, or other processes may be used to form electronic device 100.

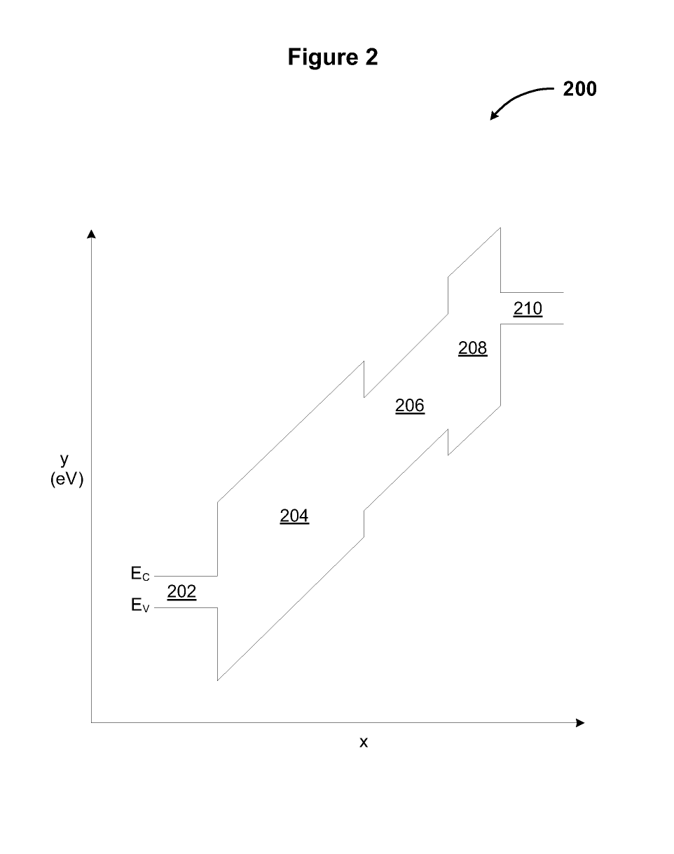

FIG. 2 is a band diagram of an electronic device comprising a tunnel dielectric structure as described herein, according to but one embodiment. In an embodiment, band diagram 200 depicts a typical erase condition of an electronic device. In another embodiment, band diagram 200 is a qualitative depiction of bandgap energy (eV) in the y direction through various components of an electronic device 100 in the x direction. Band diagram 200 may depict bandgaps comprising a conduction band (Ec) energy and valence band (Ev) energy for a semiconductor channel 202, a first tunnel dielectric 204, a second tunnel dielectric 206, a third tunnel dielectric 208, and a charge trap structure 210 such as a floating gate.

Band diagram 200 may depict bandgaps for a tunneling dielectric structure 108 in accordance with embodiments described herein. In an embodiment, a bandgap for a second tunnel dielectric 206 is relatively smaller than a bandgap for a first tunnel dielectric 204 and relatively smaller than a bandgap for a third tunnel dielectric 208. A smaller bandgap may facilitate or increase electron tunneling through second tunnel dielectric 204. For example, in an erase condition where a voltage is applied to a charge trap structure comprising a bandgap 210, electron tunneling from the charge trap structure to a semiconductor channel having a bandgap 202 may be increased by the relatively smaller bandgap of the second tunnel dielectric 206. Increased tunneling may allow a lower voltage to be applied for an erase condition.

In an embodiment, a bandgap for a second tunnel dielectric 206 is selected to allow programming of an electronic device 100 already described. A bandgap for a first tunnel dielectric 204 may be selected to provide charge retention in an electronic device 100 and a bandgap for a third tunnel dielectric 208 may be selected to allow electron tunneling to a semiconductor channel having a bandgap 202.

In one embodiment, a bandgap for a semiconductor channel 202 comprising silicon (Si) is about 1.10 eV to about 1.13 eV, a bandgap for a first tunnel dielectric 204 comprising silicon oxide (SiO₂) is about 8.5 eV to about 9.5 eV, a bandgap for a second tunnel dielectric 206 comprising silicon nitride (SiN) (Si₃N₄), tantalum pentoxide (Ta₂O₅), titanium dioxide (TiO₂), aluminum oxide (Al₂O₃), or combinations thereof is about 4.2 eV to about 5.2 eV, and a bandgap for a third tunnel dielectric 208 comprising silicon oxide (SiO₂) is about 8.5 eV to about 9.5 eV. Other materials and/or bandgaps may be used in other embodiments.

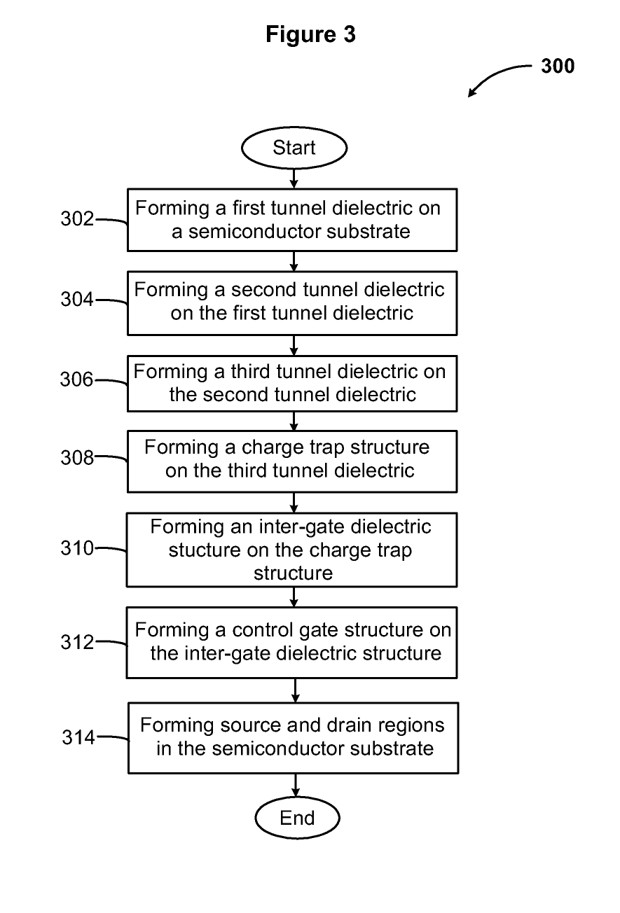

FIG. 3 is a flow diagram of a method for fabricating an electronic device comprising a tunnel dielectric structure, according to but one embodiment. In an embodiment, a method 300 includes forming a first tunnel dielectric on a semiconductor substrate at box 302, forming a second tunnel dielectric on the first tunnel dielectric at box 304, and forming a third tunnel dielectric on the second tunnel dielectric at box 306. In another embodiment, a method 300 further includes forming a charge trap structure on the third tunnel dielectric at box 308, forming an inter-gate dielectric structure on the charge trap structure at box 310, forming a control gate structure on the inter-gate dielectric structure at box 312, and forming source and drain regions in the semiconductor substrate at box 314.

A method 300 may include forming a first tunnel dielectric comprising a first bandgap on a semiconductor substrate 302, forming a second tunnel dielectric comprising a second bandgap on the first tunnel dielectric 304, and forming a third tunnel dielectric comprising a third bandgap on the second tunnel dielectric 306 wherein the second bandgap is relatively smaller than the first bandgap and the third bandgap. A relatively smaller second bandgap may increase electron tunneling in an electronic device such as, for example, a floating gate or trap-based flash memory device.

Forming a first tunnel dielectric 302 may comprise using an oxidation method to form a first tunnel dielectric. An oxidation method may reduce trap defects in an electronic device 100 described herein. A thermal process such as diffusion may be used to form a first tunnel dielectric 302. In an embodiment, forming a first tunnel dielectric 302 comprises forming silicon oxide (SiO₂) on a semiconductor substrate. In another embodiment, the first tunnel dielectric comprises a thickness of about 5 nm to about 7 nm wherein the first bandgap comprises about 8.5 electron volts (eV) to about 9.5 eV. Forming a first tunnel dielectric 302 may comprise using other thicknesses, materials, and/or bandgaps in other embodiments including embodiments already described herein with respect to FIGS. 1 and 2. Other suitable deposition methods of a first tunnel dielectric 302 that create few or substantially no trap defects in a tunnel dielectric structure may be used in other embodiments.

Forming a second tunnel dielectric 304 may comprise depositing a second tunnel dielectric to a first tunnel dielectric using a deposition method such as chemical vapor deposition (CVD), physical vapor deposition (PVD), atomic layer deposition (ALD), or combinations thereof. In another embodiment, forming a second tunnel dielectric 304 comprises using a reduction method or other material replacement or conversion method to form a second tunnel dielectric. A reduction method may reduce trap defects in an electronic device 100 described herein. A reduction method such as plasma reduction may be used to form a second tunnel dielectric 304 by converting first tunnel dielectric material to a second tunnel dielectric material. In an embodiment, forming a second tunnel dielectric 304 comprises forming silicon nitride (SiN) (Si₃N₄), tantalum pentoxide (Ta₂O₅), titanium dioxide (TiO₂), aluminum oxide (Al₂O₃), or combinations thereof on the first tunnel dielectric.

In an embodiment, forming a second tunnel dielectric 304 comprises forming a thickness of the second tunnel dielectric that is sufficiently thin to allow programming of a transistor that incorporates the second tunnel dielectric. Reducing a thickness of a second tunnel dielectric may reduce electron trapping, which may, in turn, improve or increase programmability of a transistor that incorporates the second tunnel dielectric. In another embodiment, the thickness of the second tunnel dielectric is sufficiently thick to allow or increase electron tunneling through a multi-layer tunnel dielectric structure. In yet another embodiment, the second tunnel dielectric comprises a thickness of about 1 nm to about 2 nm wherein the second bandgap comprises about 4.2 electron volts (eV) to about 5.2 eV. Forming a second tunnel dielectric 304 may comprise using other thicknesses, materials, and/or bandgaps in other embodiments including embodiments already described herein with respect to FIGS. 1 and 2. Other suitable deposition methods of a second tunnel dielectric 304 that create few or substantially no trap defects in a tunnel dielectric structure may be used in other embodiments.

In an embodiment, forming a second tunnel dielectric 304 comprises forming few or substantially no trap defects in the second tunnel dielectric material. In another embodiment, forming a second tunnel dielectric 304 comprises forming few or substantially no trap defects at an interface between the second tunnel dielectric and the first tunnel dielectric.

Forming a third tunnel dielectric 306 may comprise using an oxidation method or other material replacement or conversion method to form a third tunnel dielectric. An oxidation method may reduce trap defects in an electronic device 100 described herein. An oxidation method such as plasma oxidation may be used to form a third tunnel dielectric 306 by converting second tunnel dielectric material to a third tunnel dielectric material. In an embodiment, forming a third tunnel dielectric 306 comprises forming silicon oxide (SiO₂) on the second tunnel dielectric. In an embodiment, forming a third tunnel dielectric 306 includes forming few or substantially no trap defects at the interface between the third tunnel dielectric and the second tunnel dielectric.

In an embodiment, forming a third tunnel dielectric 306 comprises forming a thickness of the third tunnel dielectric to be relatively smaller than a thickness of a first tunnel dielectric to increase electron tunneling to the semiconductor substrate or to increase charge retention in a transistor, or combinations thereof. In another embodiment, the third tunnel dielectric comprises a thickness of about 1.5 nm to about 2.5 nm wherein the third bandgap comprises about 8.5 electron volts (eV) to about 9.5 eV. Forming a third tunnel dielectric 306 may comprise using other thicknesses, materials, and/or bandgaps in other embodiments including embodiments already described herein with respect to FIGS. 1 and 2. Other suitable deposition methods of a third tunnel dielectric 306 that create few or substantially no trap defects in a tunnel dielectric structure may be used in other embodiments. Forming a first tunnel dielectric 302, forming a second tunnel dielectric 304, and forming a third tunnel dielectric 306 may together comprise forming a tunnel dielectric structure of a transistor that increases electron tunneling in the transistor.

A method 300 may further comprise forming a charge trap structure on a third tunnel dielectric 308, forming an inter-gate dielectric structure on the charge trap structure 310, forming a control gate structure on the inter-gate dielectric structure 312, and forming source and drain regions in the semiconductor substrate 314. Forming a charge trap structure on a third tunnel dielectric 308, forming an inter-gate dielectric structure on the charge trap structure 310, and forming a control gate structure on the inter-gate dielectric structure 312 may at least comprise deposition and patterning processes such as, for example, lithography and etch processes. Forming source and drain regions in the semiconductor substrate 314 may comprise an implant process. Method 300 may include other well-known semiconductor fabrication processes such as lithography, etch, thin films deposition, implant, planarization, diffusion, metrology, or other processes in one or more embodiments.

Various operations may be described as multiple discrete operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

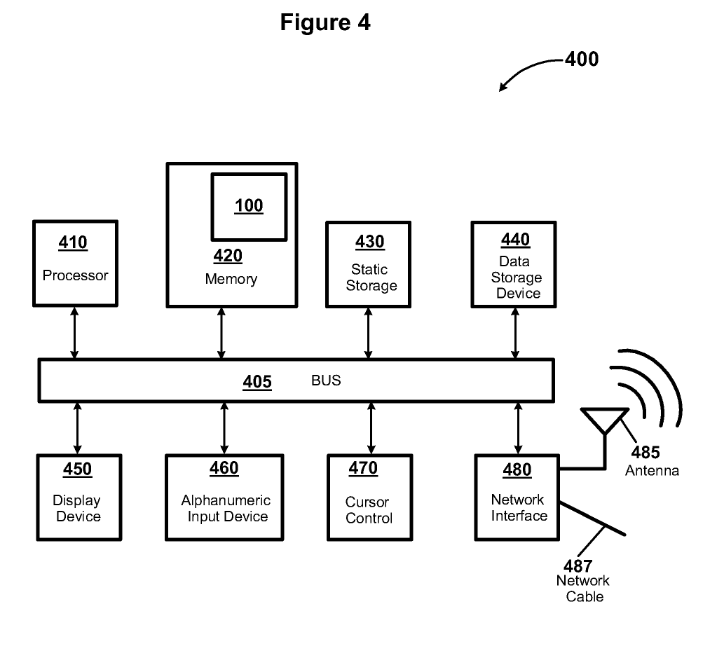

FIG. 4 is a diagram of an example system in which an electronic device comprising a tunnel dielectric structure as described herein may be used, according to but one embodiment. System 400 is intended to represent a range of electronic systems (either wired or wireless) including, for example, desktop computer systems, laptop computer systems, personal computers (PC), wireless telephones, personal digital assistants (PDA) including cellular-enabled PDAs, set top boxes, pocket PCs, tablet PCs, DVD players, or servers, but is not limited to these examples and may include other electronic systems. Alternative electronic systems may include more, fewer and/or different components.

In one embodiment, electronic system 400 includes an electronic device 100 comprising a tunnel dielectric structure in accordance with embodiments described with respect to FIGS. 1-3. In an embodiment, an electronic device 100 comprising a tunnel dielectric structure as described herein is part of an electronic system's memory 420. In an embodiment, an electronic device 100 comprising a tunnel dielectric structure as described herein comprises a p-type metal-oxide-semiconductor (PMOS) device, an n-type metal-oxide-semiconductor (NMOS) device, floating gate flash memory device, trap-based flash memory device, or combinations thereof.

Electronic system 400 may include bus 405 or other communication device to communicate information, and processor 410 coupled to bus 405 that may process information. While electronic system 400 may be illustrated with a single processor, system 400 may include multiple processors and/or co-processors. System 400 may also include random access memory (RAM) or other storage device 420 (may be referred to as memory), coupled to bus 405 and may store information and instructions that may be executed by processor 410. Memory 420 may be coupled to a processor via bus 405. In another embodiment, memory 420 is part of a processor 410 or directly coupled with a processor 410, or combinations thereof

Memory 420 may also be used to store temporary variables or other intermediate information during execution of instructions by processor 410. Memory 420 is a flash memory device in one embodiment. In an embodiment, memory 420 includes an electronic device 100 comprising a tunnel dielectric structure as described herein. In another embodiment, memory 420 includes one or more transistors, the one or more transistors comprising an electronic device 100 that includes a tunnel dielectric structure as described herein.

System 400 may also include read only memory (ROM) and/or other static storage device 430 coupled to bus 405 that may store static information and instructions for processor 410. Data storage device 440 may be coupled to bus 405 to store information and instructions. Data storage device 440 such as a magnetic disk or optical disc and corresponding drive may be coupled with electronic system 400.

Electronic system 400 may also be coupled via bus 405 to display device 450, such as a cathode ray tube (CRT) or liquid crystal display (LCD), to display information to a user. Alphanumeric input device 460, including alphanumeric and other keys, may be coupled to bus 405 to communicate information and command selections to processor 410. Another type of user input device is cursor control 470, such as a mouse, a trackball, or cursor direction keys to communicate information and command selections to processor 410 and to control cursor movement on display 450.

Electronic system 400 further may include one or more network interfaces 480 to provide access to network, such as a local area network. Network interface 480 may include, for example, a wireless network interface having antenna 485, which may represent one or more antennae. Network interface 480 may also include, for example, a wired network interface to communicate with remote devices via network cable 487, which may be, for example, an Ethernet cable, a coaxial cable, a fiber optic cable, a serial cable, or a parallel cable.

In one embodiment, network interface 480 may provide access to a local area network, for example, by conforming to an Institute of Electrical and Electronics Engineers (IEEE) standard such as IEEE 802.11b and/or IEEE 802.11g standards, and/or the wireless network interface may provide access to a personal area network, for example, by conforming to Bluetooth standards. Other wireless network interfaces and/or protocols can also be supported.

IEEE 802.11b corresponds to IEEE Std. 802.11b-1999 entitled “Local and Metropolitan Area Networks, Part 11: Wireless LAN Medium Access Control (MAC) and Physical Layer (PHY) Specifications: Higher-Speed Physical Layer Extension in the 2.4 GHz Band,” approved Sep. 16, 1999 as well as related documents. IEEE 802.11g corresponds to IEEE Std. 802.11g-2003 entitled “Local and Metropolitan Area Networks, Part 11: Wireless LAN Medium Access Control (MAC) and Physical Layer (PHY) Specifications, Amendment 4: Further Higher Rate Extension in the 2.4 GHz Band,” approved Jun. 27, 2003 as well as related documents. Bluetooth protocols are described in “Specification of the Bluetooth System: Core, Version 1.1,” published Feb. 22, 2001 by the Bluetooth Special Interest Group, Inc. Previous or subsequent versions of the Bluetooth standard may also be supported.

In addition to, or instead of, communication via wireless LAN standards, network interface(s) 480 may provide wireless communications using, for example, Time Division, Multiple Access (TDMA) protocols, Global System for Mobile Communications (GSM) protocols, Code Division, Multiple Access (CDMA) protocols, and/or any other type of wireless communications protocol.

In an embodiment, a system 400 includes one or more omnidirectional antennae 485, which may refer to an antenna that is at least partially omnidirectional and/or substantially omnidirectional, and a processor 410 coupled to communicate via the antennae.

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of the description, as those skilled in the relevant art will recognize.

These modifications can be made in light of the above detailed description. The terms used in the following claims should not be construed to limit the scope to the specific embodiments disclosed in the specification and the claims. Rather, the scope of the embodiments disclosed herein is to be determined by the following claims, which are to be construed in accordance with established doctrines of claim interpretation.

What is claimed is:

1. An apparatus comprising:
a semiconductor substrate;
a first tunnel dielectric comprising a first bandgap coupled to the semiconductor substrate;
a second tunnel dielectric comprising a second bandgap coupled to the first tunnel dielectric; and
a third tunnel dielectric comprising a third bandgap coupled to the second tunnel dielectric wherein the second bandgap is relatively smaller than the first bandgap and the third bandgap.

2. An apparatus according to claim 1 wherein the first tunnel dielectric comprises silicon oxide (SiO₂), the second tunnel dielectric comprises silicon nitride (SiN) (Si₃N₄), tantalum pentoxide (Ta₂O₅), titanium dioxide (TiO₂), aluminum oxide (Al₂O₃), or combinations thereof, and the third tunnel dielectric comprises silicon oxide (SiO₂).

3. An apparatus according to claim 1 wherein the first tunnel dielectric comprises a thickness that is relatively larger than a thickness of the third tunnel dielectric to increase charge retention in a device and wherein the thickness of the third tunnel dielectric is relatively smaller than the thickness of the first tunnel dielectric to allow electron tunneling to the semiconductor substrate.

4. An apparatus according to claim 1 wherein the first tunnel dielectric comprises a thickness of about 5 nanometers (nm) to about 7 nm, the second tunnel dielectric comprises a thickness of about 1 nm to about 2 nm, and the third tunnel dielectric comprises a thickness of about 1.5 nm to about 2.5 nm.

5. An apparatus according to claim 1 wherein the first bandgap comprises about 8.5 electron volts (eV) to about 9.5 eV, the second bandgap comprises about 4.2 eV to about 5.2 eV, and the third bandgap comprises about 8.5 eV to about 9.5 eV.

6. An apparatus according to claim 1 wherein the second tunnel dielectric comprises few or substantially no trap defects in the second tunnel dielectric material and further comprises few or substantially no trap defects at the interfaces between the second tunnel dielectric and the first and third tunnel dielectrics wherein the second tunnel dielectric comprises a thickness that is sufficiently thin to allow programming of a device that incorporates the second tunnel dielectric and wherein the thickness of the second tunnel dielectric is sufficiently thick to allow or increase electron tunneling in the device.

7. An apparatus according to claim 1 further comprising a device wherein the first tunnel dielectric, the second tunnel dielectric, and the third tunnel dielectric form a tunnel dielectric structure of the device that increases electron tunneling in the device, the device comprising:
a charge trap structure coupled to the third tunnel dielectric;
an inter-gate dielectric structure coupled to the charge trap structure;
a control gate structure coupled to the inter-gate dielectric structure;
a source region in the semiconductor substrate coupled to the first tunnel dielectric; and
a drain region in the semiconductor substrate coupled to the first tunnel dielectric.

8. A method comprising:
forming a first tunnel dielectric comprising a first bandgap on a semiconductor substrate;
forming a second tunnel dielectric comprising a second bandgap on the first tunnel dielectric; and
forming a third tunnel dielectric comprising a third bandgap on the second tunnel dielectric wherein the second bandgap is relatively smaller than the first bandgap and the third bandgap.

9. A method according to claim 8 wherein forming the first tunnel dielectric comprises using an oxidation method to form a first tunnel dielectric comprising silicon oxide (SiO₂), the first tunnel dielectric comprising a thickness of about 5 nm to about 7 nm wherein the first bandgap comprises about 8.5 electron volts (eV) to about 9.5 eV.

10. A method according to claim 8 wherein forming the second tunnel dielectric comprises forming silicon nitride (SiN) (Si₃N₄), tantalum pentoxide (Ta₂O₅), titanium dioxide (TiO₂), aluminum oxide (Al₂O₃), or combinations thereof on the first tunnel dielectric, the second tunnel dielectric comprising a thickness of about 1 nm to about 2 nm wherein the second bandgap comprises about 4.2 electron volts (eV) to about 5.2 eV.

11. A method according to claim 8 wherein forming the third tunnel dielectric comprises using an oxidation method to form a third tunnel dielectric comprising silicon oxide (SiO₂), the third tunnel dielectric comprising a thickness of about 1.5 nm to about 2.5 nm wherein the third bandgap comprises about 8.5 electron volts (eV) to about 9.5 eV.

12. A method according to claim 8 wherein forming the third tunnel dielectric comprises forming a thickness of the third tunnel dielectric to be relatively smaller than a thickness of the first tunnel dielectric to increase electron tunneling to the semiconductor substrate or to increase charge retention in a device, or combinations thereof.

13. A method according to claim 8 wherein forming the second tunnel dielectric comprises forming few or substantially no trap defects in the second tunnel dielectric material and few or substantially no trap defects at an interface between the second tunnel dielectric and the first tunnel dielectric and wherein forming the third tunnel dielectric comprises forming few or substantially no trap defects at the interface between the third tunnel dielectric and the second tunnel dielectric, the second tunnel dielectric comprising a thickness that is sufficiently thin to allow programming of a device that incorporates the second tunnel dielectric and sufficiently thick to allow or increase electron tunneling in the device.

14. A method according to claim 8 wherein forming the first tunnel dielectric, forming the second tunnel dielectric, and forming the third tunnel dielectric together comprise forming a tunnel dielectric structure of a device that increases electron tunneling in the device, the method further comprising:
forming a charge trap structure on the third tunnel dielectric;
forming an inter-gate dielectric structure on the charge trap structure;
forming a control gate structure on the inter-gate dielectric structure; and
forming source and drain regions in the semiconductor substrate.

15. A system comprising:
a processor; and
a memory coupled with the processor, wherein the memory comprises one or more devices, the one or more devices comprising:
a semiconductor substrate;
a first tunnel dielectric comprising a first bandgap coupled to the semiconductor substrate;
a second tunnel dielectric comprising a second bandgap coupled to the first tunnel dielectric; and
a third tunnel dielectric comprising a third bandgap coupled to the second tunnel dielectric wherein the second bandgap is relatively smaller than the first bandgap and the third bandgap.

16. A system according to claim 15 wherein the memory comprises an n-type or p-type metal-oxide-semiconductor device, floating gate flash memory device, trap-based flash memory device, or combinations thereof, and wherein the first tunnel dielectric comprises silicon oxide (SiO₂), the second tunnel dielectric comprises silicon nitride (SiN) (Si₃N₄), tantalum pentoxide (Ta₂O₅), titanium dioxide (TiO₂), aluminum oxide (Al₂O₃), or combinations thereof, and the third tunnel dielectric comprises silicon oxide (SiO₂).

17. A system according to claim 15 wherein the first tunnel dielectric comprises a thickness that is relatively larger than a thickness of the third tunnel dielectric to increase charge retention in the one or more devices and wherein the thickness of the third tunnel dielectric is relatively smaller than the thickness of the first tunnel dielectric to allow electron tunneling to the semiconductor substrate.

18. A system according to claim 15 wherein the first tunnel dielectric comprises a thickness of about 5 nm to about 7 nm, the second tunnel dielectric comprises a thickness of about 1 nm to about 2 nm, the third tunnel dielectric comprises a thickness of about 1.5 nm to about 2.5 nm, and wherein the first bandgap comprises about 8.5 electron volts (eV) to about 9.5 eV, the second bandgap comprises about 4.2 eV to about 5.2 eV, and the third bandgap comprises about 8.5 eV to about 9.5 eV.

19. A system according to claim 15 wherein the second tunnel dielectric comprises few or substantially no trap defects in the second tunnel dielectric material and further comprises few or substantially no trap defects at the interfaces between the second tunnel dielectric and the first and third tunnel dielectrics wherein the second tunnel dielectric comprises a thickness that is sufficiently thin to allow programming of the one or more devices and wherein the thickness of the second tunnel dielectric is sufficiently thick to allow or increase electron tunneling in the one or more devices.

20. A system according to claim 15 wherein the first tunnel dielectric, the second tunnel dielectric, and the third tunnel dielectric form a tunnel dielectric structure of the one or more devices that increases electron tunneling in the one or more devices, the one or more devices further comprising:
a charge trap structure coupled to the third tunnel dielectric;
an inter-gate dielectric structure coupled to the charge trap structure;
a control gate structure coupled to the inter-gate dielectric structure;
a source region in the semiconductor substrate coupled to the first tunnel dielectric; and
a drain region in the semiconductor substrate coupled to the first tunnel dielectric.
